(19) United States
(12) Patent Application Publication
(10) Pub. No.: US 2026/0088803 A1
(43) Pub. Date: Mar. 26, 2026

(54) PROACTIVE VOLTAGE OVERSHOOT MITIGATION

(71) Applicant: QUALCOMM Incorporated, San Diego, CA (US)

(72) Inventors: Vijay Kiran KALYANAM, Austin, TX (US); Eric Wayne MAHURIN, Austin, TX (US); Hitesh Kumar GUPTA, Sunnyvale, CA (US); Suresh Kumar VENKUMAHANTI, Austin, TX (US)

(21) Appl. No.: 18/898,107

(22) Filed: Sep. 26, 2024

(51) Int. Cl. H03H 17/02; G05B 13/04

(52) U.S. Cl. CPC H03H 17/02; G05B 13/048

(57) ABSTRACT

Aspects of the disclosure are directed to proactive voltage overshoot mitigation (PVM) overshoot voltage mitigation. In accordance with one aspect, the disclosure includes a processing engine; a digital filter coupled to the processing engine, the digital filter configured to model a power delivery network (PDN) in combination with the instruction sequences for voltage overshoot mitigation for the processing engine; and a controller coupled to the digital filter, the controller configured to transfer a plurality of digital filter parameters to the digital filter.

### TECHNICAL FIELD

This disclosure relates generally to the electronic power supplies, and, in particular, to mitigation of voltage overshoot in electronic power supplies.

### BACKGROUND

An electronic power supply provides a source of electrical energy to an electrical load. In most scenarios, the electronic power supply provides the electrical energy source at a voltage level and the electrical load draws a particular current level depending on a load demand. In an ideal case, the voltage level should be constant, independent of current level. However, a rapid transition from a high current load to a high current load may cause a voltage overshoot due to the power delivery network composed of R (Resistance), L (Inductor) and C (capacitor) components. Thus, mitigation of voltage overshoot in an electronic power supply may be needed for proper performance.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

In one aspect, the disclosure provides proactive voltage overshoot mitigation (PVM) overshoot voltage mitigation. Accordingly, the present disclosure discloses an apparatus including: a processing engine; a digital filter coupled to the processing engine, the digital filter configured to model a power delivery network (PDN) for voltage overshoot mitigation for the processing engine; and a controller coupled to the digital filter, the controller configured to transfer a plurality of digital filter parameters to the digital filter.

In one example, the apparatus further includes a table of instructions to be executed by the processing engine coupled to the digital filter, the table configured to generate a plurality of energy estimates for the digital filter. In one example, the digital filter is further configured to generate a predicted voltage output based on the plurality of energy estimates. In one example, the apparatus further includes a proactive voltage overshoot mitigation (PVM) module coupled to the digital filter, the PVM module configured to generate a voltage overshoot control signal based on the predicted voltage output. In one example, the PVM module is further configured to apply the voltage overshoot control signal to the processing engine. In one example, the apparatus further includes a table of instructions to be executed by the processing engine to generate a plurality of energy estimates for the digital filter.

Another aspect of the disclosure provides an apparatus including: means for configuring a digital filter to model a power delivery network (PDN) for voltage overshoot mitigation for a processing engine; means for configuring energy estimates for the digital filter; and means for generating a predicted voltage output based on the plurality of energy estimates.

In one example, the digital filter is a second order digital infinite impulse response (IIR) bandpass filter. In one example, the apparatus further includes means for generating a voltage overshoot control signal based on the predicted voltage output to adapt instruction issue control; and means for applying the voltage overshoot control signal to the processing engine. In one example, the apparatus further includes means for transferring a plurality of digital filter parameters when configuring the digital filter, and wherein the plurality of digital filter parameters depends on filter coefficients. In one example, the apparatus further includes means for generating the plurality of energy estimates from an instruction issue sequence, and wherein the plurality of energy estimates is a plurality of energy per clock cycle per cycle estimates.

Another aspect of the disclosure provides a method including: configuring a digital filter to model a power delivery network (PDN) for voltage overshoot mitigation for a processing engine; configuring a plurality of energy estimates for the digital filter; and generating a predicted voltage output based on the plurality of energy estimates. In one example, the digital filter is an Nth order digital infinite impulse response (IIR) bandpass filter. In one example, the digital filter is a second order digital infinite impulse response (IIR) bandpass filter.

In one example, the method further includes transferring a plurality of digital filter parameters when configuring the digital filter. In one example, the plurality of digital filter parameters depends on filter coefficients. In one example, the method further includes generating a voltage overshoot control signal based on the predicted voltage output to adapt instruction issue control. In one example, the method further includes applying the voltage overshoot control signal to the processing engine.

In one example, the plurality of energy estimates is a plurality of energy per cycle per clock cycle estimates. In one example, the plurality of energy estimates is a plurality of maximum energy per cycle per clock cycle estimates. In one example, the method further includes generating the plurality of energy estimates from an instruction issue sequence.

These and other aspects of the present disclosure will become more fully understood upon a review of the detailed description, which follows. Other aspects, features, and implementations of the present disclosure will become apparent to those of ordinary skill in the art, upon reviewing the following description of specific, exemplary implementations of the present invention in conjunction with the accompanying figures. While features of the present invention may be discussed relative to certain implementations and figures below, all implementations of the present invention can include one or more of the advantageous features discussed herein. In other words, while one or more implementations may be discussed as having certain advantageous features, one or more of such features may also be used in accordance with the various implementations of the invention discussed herein. In similar fashion, while exemplary implementations may be discussed below as device, system, or method implementations it should be understood that such exemplary implementations can be implemented in various devices, systems, and methods.

### BRIEF DESCRIPTION OF THE DRAWINGS

FIG. 1 illustrates an example processing engine voltage overshoot hardware design.

FIG. 2 illustrates an example proactive voltage overshoot mitigation (PVM) voltage overshoot prediction circuit.

FIG. 3 illustrates an example proactive voltage overshoot mitigation (PVM) overshoot circuit.

FIG. 4 illustrates an example proactive voltage overshoot mitigation (PVM) state transition diagram.

FIG. 5 illustrates an example flow diagram for implementing proactive voltage overshoot mitigation (PVM).

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

While for purposes of simplicity of explanation, the methodologies are shown and described as a series of acts, it is to be understood and appreciated that the methodologies are not limited by the order of acts, as some acts may, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

An electrical load requires electrical energy for its proper operation. A source of electrical energy is an electronic power supply. The electronic power supply is characterized by two key parameters: voltage level and current level, where the product of voltage level and current level specifies electrical power (i.e., rate of change of electrical energy delivery). The current level depends on the electrical load for a given voltage level. Ideally, the voltage level is constant, independent of the current level. If the current level is dynamic, due to changing electrical load demands over time, the electrical power being delivered by the electronic power supply is also dynamic. As a result, a rapid transition between a high current load to a low current load may cause a voltage overshoot, that is, a voltage exceedance.

In one example, a voltage overshoot may translate to a transistor overvoltage event in the electrical load. For example, the transistor overvoltage event may result in hold-time failures. In one example, hold-time refers to a minimum time period for electronic circuit signal stability (e.g., a minimum time period to allow sampling). In one example, a plurality of transistor overvoltage events, particularly those with high voltage magnitude and large quantity, may degrade electrical load reliability and result in a failure. In one example, recent trends in high performance machine learning (ML) and artificial intelligence (AI) platforms drive increasing current level dynamic behavior in processing engines (e.g., central processing unit, graphics processing unit, etc.) with rapid transitions between a high power current load and a low power current load. That is, transient current level demands may cause voltage overshoot noise issues.

A solution for voltage overshoot mitigation is a proactive voltage overshoot mitigation (PVM) module. In one example, the PVM module implements a voltage control mechanism for reducing a rate of voltage overshoot events in a processing engine. In one example, the voltage control mechanism employs a sequence of control directives. In one example, the sequence of control directives implements an instruction issue control. In one example, the instruction issue control can slowdown and may be traded for instruction execution performance.

In one example, the PVM module uses instruction issue information, cycles of work information, and a configuration register (CR) for a power delivery network (PDN) model to adapt instruction issue control for voltage overshoot control. The instruction issue pacing modulates state changes in the PVM module. Cycles of work is a measure of a quantity of pending transactions. In one example, the PVM module prevents a stall which may cause a voltage overshoot and instead introduces an instruction issue, when ready to execute, to reduce voltage overshoot frequency and magnitude. The instruction issue controls potentially introducing stalls in an instruction pipeline. For example, the instruction issue controls sequence of instructions held in energy table or instruction issue queue.

In one example, the PVM module includes two phases: detection and mitigation. In one example, the voltage overshoot may be detected by using the PDN model in the PVM module by tracking processing engine instruction issue sequences. Alternatively, the PDN model may be based on digital power meter (DPM) measurements. In one example, the PVM module may use cycles of work (e.g., quantity of pending transactions) to make voltage overshoot control decisions.

Voltage overshoot may be mitigated by an instruction issue controlling slowdown process where control of instruction issue is regulated by introduction of stalls in a processing engine pipeline. In one example, the instruction issue pacing slowdown is executed upon detection of the voltage overshoot. In one example, the instruction issue controlling slowdown operates in an instruction pipeline. For example, the instruction issue controls sequence of instructions held in a table or queue.

In one example, the PVM module mitigates voltage overshoot without need of dummy instruction execution or without use of other transactions which waste dc power. In one example, the PVM module reduces frequency of hold-time failures by increasing hold-time margin. In one example, usage of high-voltage transistor/standard cell library models with the PVM module allows relaxed timing closure constraints and alleviates device reliability concerns.

In one example, a proactive voltage overshoot mitigation (PVM) module predicts supply voltage transients in a processing engine and adapts instruction issue controlling of the processing engine to reduce a supply voltage. Each processing engine of a plurality of processing engines may have a dedicated PVM module. For example, each PVM module may have a corresponding configuration register (CR). In one example, the PVM module may use a digital power meter (DPM) which models processing engine power consumption per clock cycle based on microarchitecture events. In one example, the PVM module may use processing engine instruction issue sequencing instead of the DPM.

In one example, the PVM module may include a configurable digital bandpass filter for modeling the PDN to predict a voltage response from DPM measurements or instruction issue sequencing. In one example, the digital bandpass filter is a second order infinite impulse response (IIR) filter. In one example, when the digital bandpass filter coupled with instruction sequences anticipates a potential voltage overshoot event, the PVM module may adapt instruction issue sequencing to slow down processing engine instruction execution. In one example, the adapted instruction issue sequencing reduces voltage overshoot magnitude.

In one example, a processing engine may implement the PVM module based on processing engine instruction issue sequence and a PDN model to mitigate a voltage overshoot transient.

In one example, the processing engine may implement a PVM voltage overshoot ramp down to ramp down instruction issue slowly.

In one example, the PVM voltage overshoot ramp down reduces a number of occurrences of voltage overshoot events during a processing engine workload execution with a tradeoff on performance.

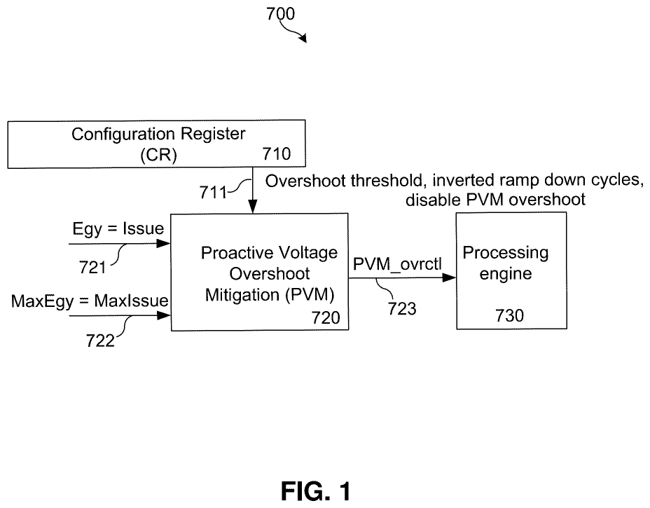

FIG. 1 illustrates an example processing engine voltage overshoot hardware design 700. In one example, the processing engine voltage overshoot hardware design 700 includes a configuration register (CR) 710, a PVM module 720 and a processing engine 730. In one example, the PVM module 720 receives an energy per clock cycle (Egy) estimate 721 from an Issue estimate and a maximum energy per clock cycle (MaxEgy) estimate 722 from a MaxIssue estimate. In one example, the CR 710 also supplies a plurality of PVM parameters 711 to the PVM module 720. Issue and MaxIssue are based on the processing engine issuing (or not issuing) in a clock cycle and maximum instructions that can be issued in a clock cycle. In one example, the PDN model is used to model a PDN impedance profile to predict a voltage response from a sequence of processing engine DPM measurements and a plurality of PVM parameters.

In one example, the DPM produces these the Egy estimate 721 and the MaxEgy estimate 722 based on microarchitecture events by applying a plurality of DPM weights obtained from the CR to each microarchitecture event. For example, the plurality of PVM parameters 711 includes an overshoot threshold, an inverted ramp down cycle count, a disable PVM overshoot state, etc. One skilled in the art would understand that the listed PVM parameters are not exclusive and that other PVM parameters may be included within the spirit and scope of the present disclosure. In one example, the PVM 720 provides a PVM control (PVM_ovrctl) signal 723 to the processing engine 730 to adapt instruction issue sequencing in an instruction pipeline.

In one example, the PVM module 720 interfaces with the Issue estimate, the MaxIssue estimate and the CR 710 to control and adapt instruction issue of the processing engine 730 via the PVM control (PVM_ovrctl) signal 723. In which one example, the CR 710 contains configuration registers that includes all PVM parameters that includes Filter parameters for a PDN model for voltage overshoot control, overshoot threshold (over), inverted ramp down cycles etc. In one example, the PVM control (PVM_ovrctl) signal 723 is a local control signal for introducing ramp down stalls in a processing engine instruction pipeline.

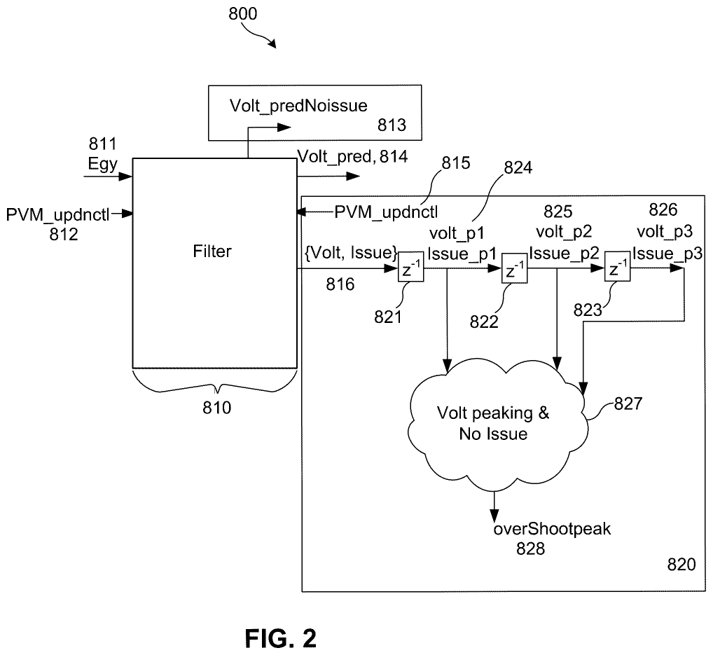

FIG. 2 illustrates an example proactive voltage overshoot mitigation (PVM) voltage overshoot prediction circuit 800. In one example, the PVM voltage overshoot prediction circuit 800 includes a configurable 2^{nd} order digital IIR bandpass filter 810 to provide voltage (V_{DD}) response per clock cycle from a sequence of processing engine DPM measurements or from a sequence of processing engine instruction issues. In one example, the digital filter 810 predicts a voltage response from a sequence of processing engine DPM measurements or from a sequence of processing engine instruction issues and a plurality of PVM parameters. In one example, the bandpass filter 810 receives an energy per clock cycle (Egy) estimate 811, a first PVM up/down control signal 812 and a second PVM up/down control signal 815. In one example, the bandpass filter 810 provides a no issue voltage prediction (volt_predNoIssue) 813 when there is no instruction issue. In one example, the bandpass filter 810 provides an issue voltage prediction (volt_pred) 814 when there is an instruction issue.

In one example, the bandpass filter 810 provides a voltage prediction 816 to an overshoot peaking prediction circuit 820. In one example, the overshoot peaking prediction circuit 820 propagates the voltage prediction 816 and instruction issue signals to a first delay element 821 to produce a first voltage, issue state 824, then to a second delay element 822 to produce a second voltage, issue state 825, then to a third delay element 823 to produce a third voltage, issue state 826. In one example, the first voltage, issue state 824, second voltage, issue state 825 and the third voltage, issue state 826 are delivered to a voltage peaking when there is no instruction issue processing circuit 827 to produce an overshoot peaking (overShootpeak) signal 828 to indicate that a predicted voltage response is peaking with a voltage overshoot when there is no instruction issue.

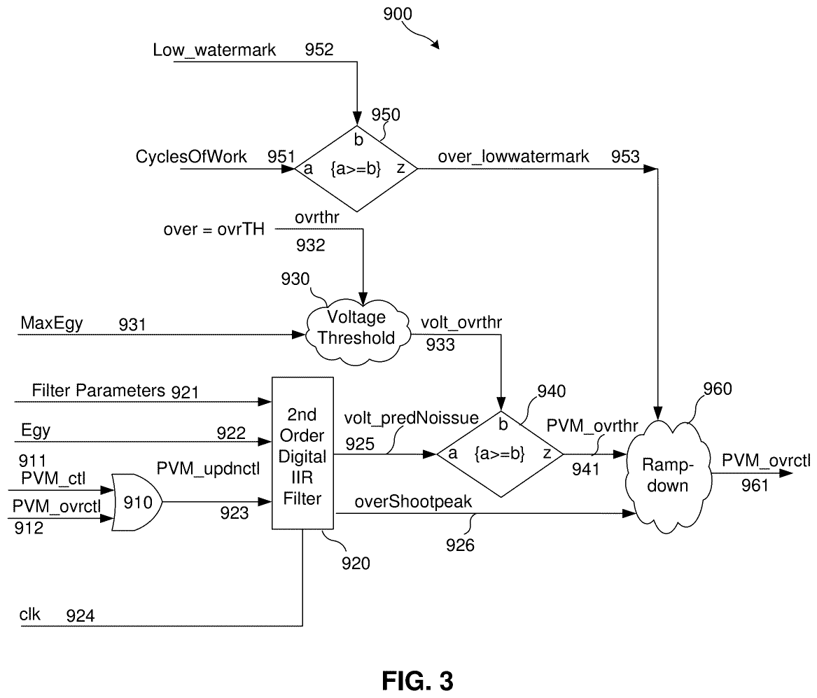

FIG. 3 illustrates an example proactive voltage overshoot mitigation (PVM) overshoot circuit 900. In one example, a digital OR gate 910 accepts a PVM control (PVM_ctl) signal 911 as a first input and a PVM overcontrol (PVM_ovrctl) signal 912 to produce a PVM up/down control (PVM_updnctl) signal 923 as an output.

In one example, a 2^{nd} order digital IIR filter 920 accepts a plurality of Filter parameters 921 as a first input, an energy per clock cycle (Egy) estimate 922 as a second input and the PVM up/down control (PVM_updnctl) signal 923 as a third input to produce a no issue voltage prediction (volt_predNoIssue) 925 as a first output and an overshoot peaking (overShootpeak) signal 926 as a second output. In one example, the 2^{nd} order digital IIR filter 920 operates synchronously using a clock signal (clk) 924. In one example, the plurality of Filter parameters 921 includes filter coefficients. One skilled in the art would understand that the listed filter parameters are not exclusive and that other parameters may be included within the spirit and scope of the present disclosure.

In one example, a voltage threshold scaler 930 accepts a maximum energy per clock cycle (MaxEgy) estimate 931 as a first scaler input and an overshoot threshold (ovrth) level 932 as a second scaler input to produce a voltage overshoot threshold (volt_ovrthr) 933 as a calibrated threshold output. That is, the overshoot threshold 932 is scaled by the maximum energy per clock cycle estimate 931 for calibration of the voltage overshoot threshold for a given scenario.

In one example, a first decision tree 940 accepts the no issue voltage prediction (volt_predNoIssue) 925 as a first tree input and the voltage overshoot threshold (volt_ovrthr) 933 as a second tree input to determine a PVM overvoltage threshold (PVM_ovrthr) 941, depending on a comparison between the first tree input 925 and the second tree input 933, as shown in FIG. 3.

In one example, a second decision tree 950 accepts a CyclesOfWork parameter 951 and a low watermark (Low_watermark) parameter 952 as its two inputs to determine an overvoltage low watermark level (over_lowwatermark) 953, depending on a comparison between the two inputs, as shown in FIG. 3. In one example, the CyclesOfWork parameter 951 is computed based on a quantity instruction issue transactions which are pending. For example, when a new instruction is allocated into the energy table or table of instruction issue queue, the CyclesOfWork parameter 951 is associated with that new instruction. In one example, a value of the CyclesOfWork parameter 951 decreases as transactions are issued. In one example, the CyclesOfWork parameter 951 increases as new work arrives or does not increase for decreasing or equal work across cycles.

In one example, a ramp down scaler 960 accepts the PVM overvoltage threshold (PVM_ovrthr) 941, the overshoot peaking (overShootpeak) signal 926 and the overvoltage low watermark level (over_lowwatermark) 953 to produce a PVM overvoltage control (PVM_ovrctl) signal 961. In one example, usage of the low watermark (Low_watermark) parameter 952 and the calibration of the overshoot threshold (ovrth) level 932 are applied to improve overall PVM performance.

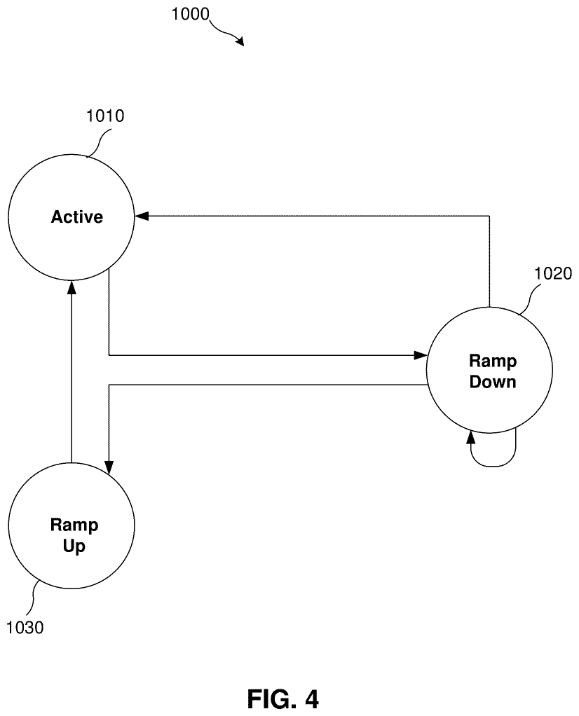

In one example, a PVM module transitions among a plurality of PVM states, for example, Active, Ramp Down, Ramp Up, etc. FIG. 4 illustrates an example proactive voltage overshoot mitigation (PVM) state transition diagram 1000. In one example, the PVM state transition diagram 1000 includes an Active state 1010, a Ramp Down state 1020 and a Ramp Up state 1030. In one example, it transitions between these states dependent on changes over_lowwatermark and CyclesOfWork.

In one example, the PVM module implements a ramp down policy to generate a PVM overvoltage control (PVM_ovrctl) signal, depending on a plurality of conditions. For example, if the no issue voltage prediction (volt_predNoIssue) is less than a negative of the voltage overshoot threshold (volt_ovrthr), then the PVM module does not assert the PVM overvoltage control (PVM_ovrctl) signal. That is, the PVM module prevents a stall which may cause a voltage overshoot and instead introduces an instruction issue (when ready to execute) to reduce the voltage overshoot magnitude.

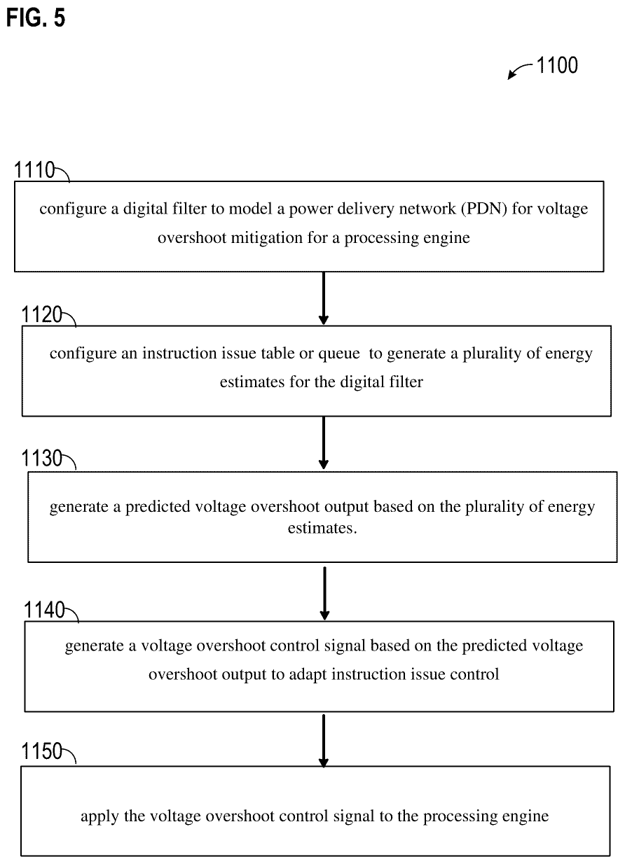

FIG. 5 illustrates an example flow diagram for implementing proactive voltage overshoot mitigation (PVM) 1100. In block 1110, configure a digital filter to model a power delivery network (PDN) for voltage overshoot mitigation for a processing engine. In one example, a digital filter is configured to model a power delivery network (PDN) for voltage overshoot mitigation for a processing engine. In one example, the step in block 1110 is performed by a controller, a central processing unit (CPU), a microcontroller, a microprocessor, a personal computer, a processing engine, etc.

In one example, the digital filter is an Nth order digital infinite impulse response (IIR) bandpass filter. In one example, the digital filter is a second order digital IIR bandpass filter. In one example, the configuring the digital filter includes transferring a plurality of digital filter parameters. In one example, the plurality of digital filter parameters is transferred from a non-transitory memory. In one example, the non-transitory memory is a component within a controller. In another example, the non-transitory memory is external to the controller. For example, the plurality of digital filter parameters depends on filter coefficients.

In block 1120, configure an instruction issue table or queue to generate a plurality of energy estimates for the digital filter. In one example, the step of block 1120 is performed by a controller, a central processing unit (CPU), a microcontroller, a microprocessor, a personal computer, a processing engine, etc.

In one example, the plurality of energy estimates is a plurality of energy per clock cycle estimates. In one example, the plurality of energy estimates is a plurality of maximum energy per clock cycle estimates. In one example, the plurality of DPM weights applied sequentially to a plurality of processing engine microarchitecture events every clock cycle. In one example, the plurality of energy estimates is generated from an instruction issue sequencing.

In block 1130, generate a predicted voltage overshoot output based on the plurality of energy estimates. In one example, a predicted voltage overshoot output is generated based on the plurality of energy estimates. In one example, the digital filter generates the predicted voltage output.

In block 1140, generate a voltage overshoot control signal based on the predicted voltage overshoot output to adapt instruction issue control. In one example, a voltage overshoot control signal is generated based on the predicted voltage output to adapt instruction issue control. In one example, the voltage overshoot control signal is a binary state control signal with an assert state and a de-assert state. In one example the voltage overshoot control signal is generated based on a comparison of the predicted voltage output with a calibrated voltage threshold. In one example, the calibrated voltage threshold is scaled by the plurality of energy estimates (e.g., the plurality of maximum energy per clock cycle estimates). In one example, the voltage overshoot control signal depends on a cycles of work parameter. In one example, the cycles of work parameter is a measure of a quantity of pending transactions in the instruction pipeline. In one example, the step of block 1140 is performed by a PVM module, a controller, a central processing unit (CPU), a microcontroller, a microprocessor, a personal computer, a processing engine, etc.

In block 1150, apply the voltage overshoot control signal to the processing engine. In one example, the voltage overshoot control signal is applied to the processing engine. The voltage overshoot control signal may reduce a rate of voltage overshoot events in the processing engine. In one example, the voltage overshoot control signal implements an instruction issue controlling resulting in slowdown. In one example, the instruction issue control to slowdown operates in an instruction pipeline. In one example, the step of block 1150 is performed by a PVM module, a controller, a central processing unit (CPU), a microcontroller, a microprocessor, a personal computer, a processing engine, etc.

In one aspect, one or more of the steps for providing proactive voltage overshoot mitigation (PVM) overshoot voltage mitigation in FIG. 5 may be executed by one or more processors which may include hardware, software, firmware, etc. The one or more processors, for example, may be used to execute software or firmware needed to perform the steps in the flow diagram of FIG. 5. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise.

The software may reside on a computer-readable medium. The computer-readable medium may be a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium may also include, by way of example, a carrier wave, a transmission line, and any other suitable medium for transmitting software and/or instructions that may be accessed and read by a computer. The computer-readable medium may reside in a processing system, external to the processing system, or distributed across multiple entities including the processing system. The computer-readable medium may be embodied in a computer program product. By way of example, a computer program product may include a computer-readable medium in packaging materials. The computer-readable medium may include software or firmware. Those skilled in the art will recognize how best to implement the described functionality presented throughout this disclosure depending on the particular application and the overall design constraints imposed on the overall system.

Any circuitry included in the processor(s) is merely provided as an example, and other means for carrying out the described functions may be included within various aspects of the present disclosure, including but not limited to the instructions stored in the computer-readable medium, or any other suitable apparatus or means described herein, and utilizing, for example, the processes and/or algorithms described herein in relation to the example flow diagram.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S. C. § 112, sixth paragraph, unless the element is expressly recited using the phrase “means for” or, in the case of a method claim, the element is recited using the phrase “step for.”

One skilled in the art would understand that various features of different embodiments may be combined or modified and still be within the spirit and scope of the present disclosure.

What is claimed is:

1. An apparatus comprising:
a processing engine;
a digital filter coupled to the processing engine, the digital filter configured to model a power delivery network (PDN) for voltage overshoot mitigation for the processing engine; and
a controller coupled to the digital filter, the controller configured to transfer a plurality of digital filter parameters to the digital filter.

2. The apparatus of claim 1, further comprising a table of instructions to be executed by the processing engine to generate a plurality of energy estimates for the digital filter.

3. The apparatus of claim 2, wherein the digital filter is further configured to generate a predicted voltage output based on the plurality of energy estimates.

4. The apparatus of claim 3, further comprising a proactive voltage overshoot mitigation (PVM) module comprising of the digital filter, the PVM module configured to generate a voltage overshoot control signal based on the predicted voltage output.

5. The apparatus of claim 4, wherein the PVM module is further configured to apply the voltage overshoot control signal to the processing engine.

6. An apparatus comprising:
means for configuring a digital filter to model a power delivery network (PDN) for voltage overshoot mitigation for a processing engine;
means for configuring a plurality of energy estimates for the digital filter; and
means for generating a predicted voltage output based on the plurality of energy estimates.

7. The apparatus of claim 6, wherein the digital filter is a second order digital infinite impulse response (IIR) bandpass filter.

8. The apparatus of claim 6, further comprising:
means for generating a voltage overshoot control signal based on the predicted voltage output to adapt instruction issue control; and
means for applying the voltage overshoot control signal to the processing engine.

9. The apparatus of claim 8 further comprising means for transferring a plurality of digital filter parameters when configuring the digital filter, and wherein the plurality of digital filter parameters depends on filter coefficients.

10. The apparatus of claim 9, further comprising means for generating the plurality of energy estimates from an instruction issue sequence, and wherein the plurality of energy estimates is a plurality of energy per clock cycle estimates.

11. A method comprising:
configuring a digital filter to model a power delivery network (PDN) for voltage overshoot mitigation for a processing engine;
configuring with a plurality of energy estimates for the digital filter; and
generating a predicted voltage output based on the plurality of energy estimates.

12. The method of claim 11, wherein the digital filter is an Nth order digital infinite impulse response (IIR) bandpass filter.

13. The method of claim 11, wherein the digital filter is a second order digital infinite impulse response (IIR) bandpass filter.

14. The method of claim 11 further comprising transferring a plurality of digital filter parameters when configuring the digital filter.

15. The method of claim 14, wherein the plurality of digital filter parameters depends on filter coefficients.

16. The method of claim 11, further comprising generating a voltage overshoot control signal based on the predicted voltage output to adapt instruction issue control.

17. The method of claim 16, further comprising applying the voltage overshoot control signal to the processing engine.

18. The method of claim 17, wherein the plurality of energy estimates is a plurality of energy per cycle per clock cycle estimates.

19. The method of claim 17, wherein the plurality of energy estimates is a plurality of maximum energy per cycle per clock cycle estimates.

20. The method of claim 17, further comprising generating the plurality of energy estimates from an instruction issue sequence.
